(19) United States
(12) Patent Application Publication
(10) Pub. No.: US 2023/0317323 A1
(43) Pub. Date: Oct. 5, 2023

(54) DIGITAL RESISTOR HAVING LOW AREA AND IMPROVED LINEARITY

(71) Applicant: STMicroelectronics International N.V., Geneva (CH)

(72) Inventors: Akshat KUMAR, Noida (IN); Prashutosh GUPTA, Ballia (IN)

(73) Assignee: STMicroelectronics International N.V., Geneva (CH)

(21) Appl. No.: 18/193,387

(22) Filed: Mar. 30, 2023

Related U.S. Application Data
(60) Provisional application No. 63/327,646, filed on Apr. 5, 2022.

(51) Int. Cl. H01C 10/32; H01C 10/16; G05B 19/042

(52) U.S. Cl. CPC H01C 10/32; H01C 10/16; G05B 19/0423

(57) ABSTRACT

An electronic device having a digitally controlled resistor is provided. The digitally controlled resistor includes various switch-resistor segments between voltage nodes. In one embodiment, the switch-resistor segment may include a resistor and a switch coupled parallel to the resistor. In another embodiment, the switch-resistor segment may include a resistor, a complement switch coupled in series with the resistor, and a switch coupled parallel to the resistor and the complement switch. Each switch included in the switch-resistor segment operates based on digital bits. Based on the logic value (either ‘0’ or ‘1’) assigned, the switches turn ON (when logic value is ‘1’) and OFF (when logic value is ‘0’). In some embodiments, the switches and the resistor included in the switch-transistor segment are arranged in a symmetrical manner between voltage nodes.

### BACKGROUND

### Technical Field

The present disclosure relates to a digitally-controlled resistor, which is a variable resistor that is controlled by digital bits.

### Description of the Related Art

It is beneficial for digitally-controlled resistors to be linear while providing high resolution. This, however, can be difficult to achieve with low power due to the impact of leakage currents. For instance, in ultra-low power circuit designs, switch leakages can degrade the performance of the high resolution digitally-controlled resistor.

That is, the change in digital bits leads to change in the intermediate node voltages, which in turn impacts the leakages of the switches. This leakage change due to digital code change reflects as an error in a step size (e.g., 0001 from 0010) of the digitally-controlled resistor, thereby degrading its linearity.

This technical issue is highlighted most at the mid-code change (e.g., 1000 from 0111 or vice versa) in the digitally-controlled resistor.

### BRIEF SUMMARY

Some embodiments of the present disclosure includes an electronic device. The electronic device includes a first node and a second node. The electronic device includes a first switch-resistor segment between the first node and the second node. The first switch-resistor segment includes: a first resistor having a first resistance value; a first complement switch coupled in series with the first resistor; and a first switch coupled parallel to the first resistor and the first complement switch. The first switch is switched ON when the first complement switch is OFF and the first switch is switched OFF when the first complement switch is ON.

Some embodiments of the present disclosure includes a method of operating an N-bit digitally controlled resistor. The method includes operating a first switch of a first switch-resistor segment coupled in parallel with a first resistor and a first complement switch. Operating the first switch of the first switch-resistor segment includes: turning on the first switch and turning off the first complement switch coupled in series with the first resistor having a first resistance value; or turning off the first switch and turning on the first complement switch. An operation of the first switch is indicative of a least significant bit (LSB) of the N-bit digitally controlled resistor, a ‘0’ logic value indicative of the first switch being OFF, and a ‘1’ logic value indicative of the first switch being ON,

The first resistor, the first complement switch, and the first switch defines the first switch-resistor segment between a first node and a second node opposite the first node.

Some embodiments of the present disclosure includes an electronic device. The electronic device includes an N-bit digitally controlled resistor. The N-bit digitally controlled resistor includes a first node and a second node; and a central switch-resistor segment between the first node and the second node. The central switch-resistor segment includes: a first resistor having a first resistance value; and a first switch coupled parallel to the first resistor.

The N-bit digitally controlled resistor includes a plurality of switch-resistor segments arranged symmetrically with respect to the central switch-resistor segment. A number of switch-resistor segments among the plurality of switch-resistor segments in a first section between the first node and the central switch-resistor segment and a number of switch-resistor segments among the plurality of switch-resistor segments in a second section between the second node and the central switch-resistor segment are equal to each other.

Some embodiments of the present disclosure includes a method of operating an N-bit digitally controlled resistor. The method includes controlling a first switch of a central switch-resistor segment coupled in parallel with a first resistor having a first resistance value based on a digital bit between a ‘0’ logic value and a ‘1’ logic value. Controlling the first switch of the central switch-resistor segment includes: turning on the first switch based on a digital bit of ‘1’ logic value; and turning off the first switch based on a digital bit of ‘0’ logic value.

Controlling the first switch of the central switch-resistor segment is indicative of a least significant bit (LSB) of the N-bit digitally controlled resistor.

The central switch-resistor segment is coupled between a first node and a second node.

Some embodiments of the present disclosure includes an electronic device. The electronic device includes an N-bit digitally controlled resistor. The N-bit digitally controlled resistor includes a first node and a second node; a central switch-resistor segment between the first node and the second node; and a plurality of switch-resistor segments arranged symmetrically with respect to the central switch-resistor segment.

The central switch-resistor segment includes a first resistor having a first resistance value; a first complement switch coupled in series with the first resistor; and a first switch coupled parallel to the first resistor and the first complement switch, the first switch being switched ON when the first complement switch is OFF and the first switch being switched OFF when the first complement switch is ON.

A number of switch-resistor segments among the plurality of switch-resistor segments in a first section between the first node and the central switch-resistor segment and a number of switch-resistor segments among the plurality of switch-resistor segments in a second section between the second node and the central switch-resistor segment are equal to each other.

Some embodiments of the present disclosure includes a method of operating an N-bit digitally controlled resistor. The method includes controlling a first switch of a central switch-resistor segment based on a digital bit between a ‘0’ logic value and a ‘1’ logic value. The first switch is coupled in parallel with a first resistor of the central switch-resistor segment having a first resistance value and a first complement switch of the central switch-resistor segment coupled in series with the first resistor.

The method includes controlling the first complement switch in response to the digital bit provided to the first switch. Controlling the first switch and the first complement switch of the central switch-resistor segment includes: turning on the first switch based on a digital bit of ‘1’ logic value and turning off the first complement switch; and turning off the first switch based on a digital bit of ‘0’ logic value and turning on the first complement switch.

Controlling the first switch of the central switch-resistor segment is indicative of a LSB of the N-bit digitally controlled resistor.

The central switch-resistor segment is coupled between a first node and a second node.

### BRIEF DESCRIPTION OF THE SEVERAL VIEWS OF THE DRAWINGS

Reference will now be made by way of example to the accompanying drawings. In the drawings, identical reference numbers identify similar elements or acts. In some drawings, however, different reference numbers may be used to indicate the same or similar elements. The shapes of various elements and angles are not necessarily drawn to scale, and some of these elements may be enlarged and positioned to improve drawing legibility:

FIG. 1 is a schematic circuit diagram of an N-bit digitally controlled resistor according to one embodiment of the present disclosure.

FIG. 2A is a schematic circuit diagram of a 3-bit digitally controlled resistor according to some embodiments of the present disclosure.

FIG. 2B is a table showing a resistance value between a first node and a second node of a 3-bit digitally controlled resistor and a resistor change for one code change according to some embodiments of the present disclosure.

FIG. 3 is a schematic circuit diagram of an N-bit digitally controlled resistor according to another embodiment of the present disclosure.

FIG. 4A is an example of a 4-bit digitally controlled resistor.

FIG. 4B is a table showing error when code changes from 1000 to 0111 or vice versa.

FIG. 5 is a schematic circuit diagram of an N-bit digitally controlled resistor according to yet another embodiment of the present disclosure.

FIG. 6A is an example of a 4-bit digitally controlled resistor.

FIG. 6B is a table showing error when code changes from (1000) to (0111) or vice versa.

FIG. 7 illustrates one embodiment of a switch included in the switch-resistor segment according to the present disclosure.

FIG. 8A illustrate an example approach of a digital resistor different from those shown in FIGS. 1, 2A, and 2B.

FIG. 8B illustrates a 3-bit digital resistor.

FIG. 8C illustrates a resistance value between a first voltage node and a second voltage node of the example digital resistor and a resistor change for 1 code change in the same example digital resistor.

FIG. 9A illustrates an example approach of a digital resistor different from those shown in FIGS. 3, 4A, 5, and 6A.

FIG. 9B illustrates an error at each voltage node within the example digital resistor when a code changes from (1000) to (0111) (or vice versa).

### DETAILED DESCRIPTION

Technical advantages and features of the present disclosure, and implementation methods thereof will be clarified through the following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure.

A shape, a size, a ratio, an angle, and a number disclosed in the drawings for describing embodiments of the present disclosure are merely an example. Thus, the present disclosure is not limited to the illustrated details. Like reference numerals refer to like elements throughout. In the following description, when the detailed description of the relevant known function or configuration is determined to unnecessarily obscure an important point of the present disclosure, the detailed description of such known function or configuration may be omitted.

In describing a position relationship, when a position relation between two parts is described as, for example, “on,” “over,” “under,” “adjacent,” or “next,” one or more other parts may be disposed between the two parts unless a more limiting term, such as “just” or “direct(ly),” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments as mentioned above.

As used in this specification and the appended claims, the singular forms “a,” “an,” and “the” include plural referents unless the content clearly dictates otherwise. It should also be noted that the term “or” is generally employed in its broadest sense, that is, as meaning “and/or” unless the content clearly dictates otherwise.

Digitally controlled resistor (or simply a digital resistor) is a variable resistor which is controlled by digital bits. One of the applications for these circuits is RC oscillators where the resistor value is used for trimming the output frequency. It is beneficial for digitally controlled resistors to be linear while providing high resolution which can be difficult to achieve with low power due to the impact of leakage currents. The various embodiments described herein address this technical problem.

The embodiments of the present disclosure may be applied to various technical fields including oscillators, DACs, series resistor DACs, digitally controlled resistors, circuit designs, digital potentiometers, etc.

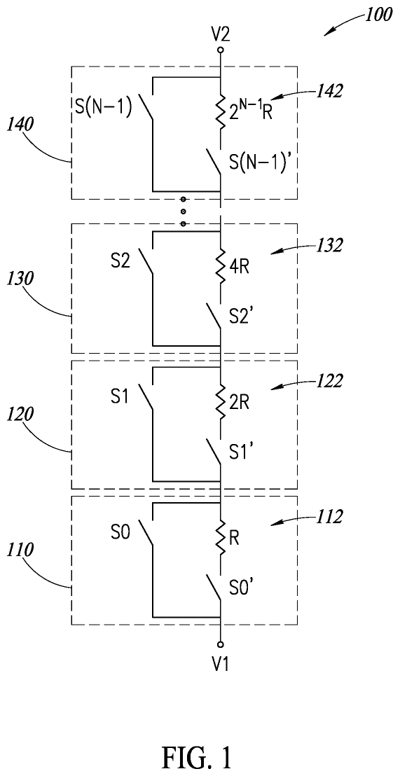

FIG. 1 is a schematic circuit diagram of an N-bit digitally controlled resistor according to one embodiment of the present disclosure.

An N-bit digitally controlled resistor 100 is shown in FIG. 1. The N-bit digitally controlled resistor 100 includes a first node (or a first voltage node) V1, a second node (or a second voltage node) V2, and one or more switch-resistor segments between the first node V1 and the second node V2. A switch-resistor segment 110 includes a first resistor 112 having a first resistance value R, a first switch S0, and a first complement switch S0′. The first switch S0 is coupled in parallel with the first resistor 112 and the first complement switch S0′ and the first complement switch S0′ is coupled in series with the first resistor 112. The first complement switch S0′ is switched ON when the first switch S0 is switched OFF. On the other hand, the first complement switch S0′ is switched OFF when the first switch S0 is switched ON. That is, during operation, the first switch S0 and the first complement switch S0′ would be in an opposite state.

Similarly, a second switch-resistor segment 120 includes a second resistor 122 having two times the resistance value of the first resistance value R (i.e., 2¹R), a second switch S1, and a second complement switch S1′. The second switch S1 is coupled in parallel with the second resistor 122 and the second complement switch S1′. The second complement switch S1′ is coupled in series with the second resistor 122. The second complement switch S1′ is switched ON when the second switch S1 is switched OFF. On the other hand, the second complement switch S1′ is switched OFF when the second switch S1 is switched ON.

The second switch-resistor segment 120 is coupled in series with the switch-resistor segment 110. The switch-resistor segment 110 may also be referred to as a first switch-resistor segment 110. For example, the first resistor 112 of the first switch-resistor segment 110 is coupled in series with the second complement switch S1′ of the second switch-resistor segment 120.

A third switch-resistor segment 130 includes a third resistor 132 having 4 times the resistance value of the first resistance value R (i.e., 2²R), a third switch S2, and a third complement switch S2′. The third switch S2 is coupled in parallel with the third resistor 132 and a third complement switch S2′. The third complement switch S2′ is coupled in series with the third resistor 132. The third complement switch S2′ is switched ON when the third switch S2 is switched OFF. On the other hand, the third complement switch S2′ is switched OFF when the third switch S2 is switched ON.

The third switch-resistor segment 130 is coupled in series with the second switch-resistor segment 120. For example, the second resistor 122 of the second switch-resistor segment 120 is coupled in series with the third complement switch S2′ of the third switch-resistor segment 130.

As shown, a plurality of switch-resistor segments may be coupled between the first node V1 and the second node V2. Similar configuration and arrangement may be repeated based on the number of the bit.

An Nth switch-resistor segment 140 includes a Nth resistor 142 having a resistance value corresponding to the first resistance value R multiplied by 2^{N-1}(i.e., 2′R), a Nth switch S(N−1), and a Nth complement switch S(N−1)′. The Nth switch S(N−1) is coupled in parallel with the Nth resistor 142 and the Nth complement switch S(N−1)′. The Nth complement switch S(N−1)′ is coupled in series with the Nth resistor 142. The Nth complement switch S(N−1)′ is switched ON when the Nth switch S(N−1) is switched OFF. On the other hand, the Nth complement switch S(N−1)′ is switched OFF when the Nth switch S(N−1) is switched ON.

In the example configuration of FIG. 1, the first switch S0 of the first switch-resistor segment 110 is indicative of a least significant bit (LSB) of the N-bit digitally controlled resistor. In addition, a ‘0’ logic value is indicative of the first switch S0 being OFF, and a ‘1’ logic value is indicative of the first switch being ON.

On the other hand, the Nth switch S(N−1) of the Nth switch-resistor segment 140 is indicative of a most significant bit (MSB) of the N-bit digitally controlled resistor.

The second switch S1 of the second switch-resistor segment 120 is indicative of the next bit adjacent to the LSB of the N-bit digitally controlled resistor and the third switch S2 of the third switch-resistor segment 130 is indicative of the next bit adjacent to that of the second switch S1 of the second switch-resistor segment 120.

A method of operating an N-bit digitally controlled resistor 100 according to FIG. 1 is also provided. The method includes operating a first switch S0 of a first switch-resistor segment 110 coupled in parallel with a first resistor 112 and a first complement switch S0′. Operating the first switch S0 of the first switch-resistor segment 110 includes turning on the first switch S0 and turning off the first complement switch S0′ and/or turning off the first switch S0 and turning on the first complement switch S0′.

The operation of the first switch S0 is indicative of a least significant bit (LSB) of the N-bit digitally controlled resistor 100. That is, a ‘0’ logic value is indicative of the first switch being OFF, and a ‘1’ logic value is indicative of the first switch being ON.

In one embodiment, the first resistor 112, the first complement switch S0′, and the first switch S0 defines the first switch-resistor segment 110.

The method also includes operating a second switch S1 of a second switch-resistor segment 120 coupled in series with the first switch-resistor segment 110. The second switch S1 is coupled parallel with a second resistor 122 and a second complement switch S1′. Operating the second switch S1 of the second switch-resistor segment 120 includes turning on the second switch S1 and turning off the second complement switch S1′ and/or turning off the second switch S1 and turning on the second complement switch S1′.

The operation of the second switch is indicative of a next highest bit adjacent to the LSB of the N-bit digitally controlled resistor 100.

When there are more than 2 switch-resistor segments (that is, if N is greater than 2), more switch-resistor segments may be coupled in series to the existing switch-resistor segment.

For example, if there are N number of switch-resistor segments, for the Nth switch-resistor segment, the method includes operating a Nth switch S(n−1) of a Nth switch-resistor segment 140 coupled in series with the (N−1)th switch-resistor segment. The Nth switch S(N−1) is coupled parallel with a Nth resistor 142 and a Nth complement switch S(N−1)′. Operating the Nth switch S(N−1) of the Nth switch-resistor segment 140 includes turning on the Nth switch S(N−1) and turning off the Nth complement switch S(N−1)′ coupled in series with the Nth resistor 142 having a resistance value 2N−1 R and/or turning off the Nth switch S(N−1) and turning on the Nth complement switch S(N−1)′.

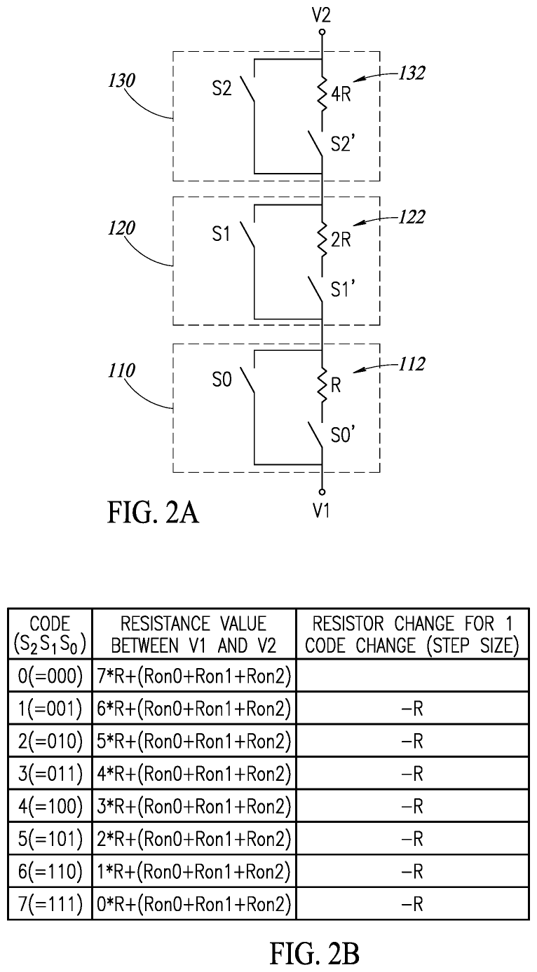

In this example of an N-bit digitally controlled resistor 100 shown in FIG. 1, N number of switch-resistor segments are included where N is a natural number. If N is 3 for a 3-bit digitally controlled resistor as shown in FIG. 2A, there will be 3 switch-resistor segments included between the first node V1 and the second node V2. The example of a 3-bit digitally controlled resistor will be explained in detail in conjunction with FIGS. 2A and 2B.

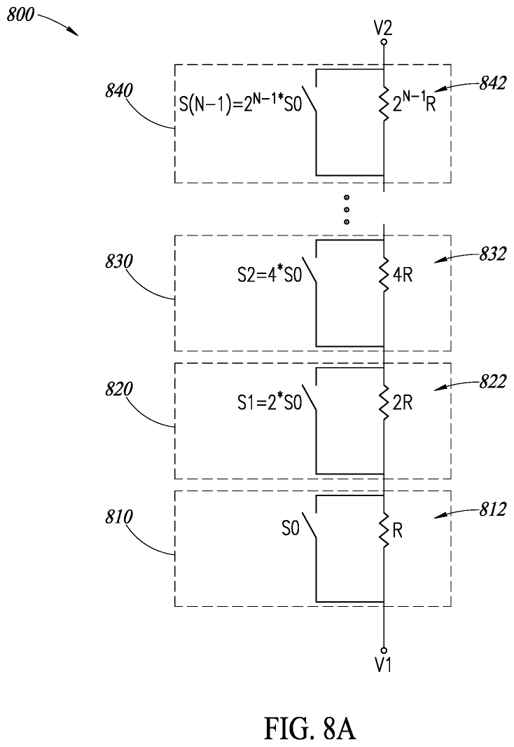

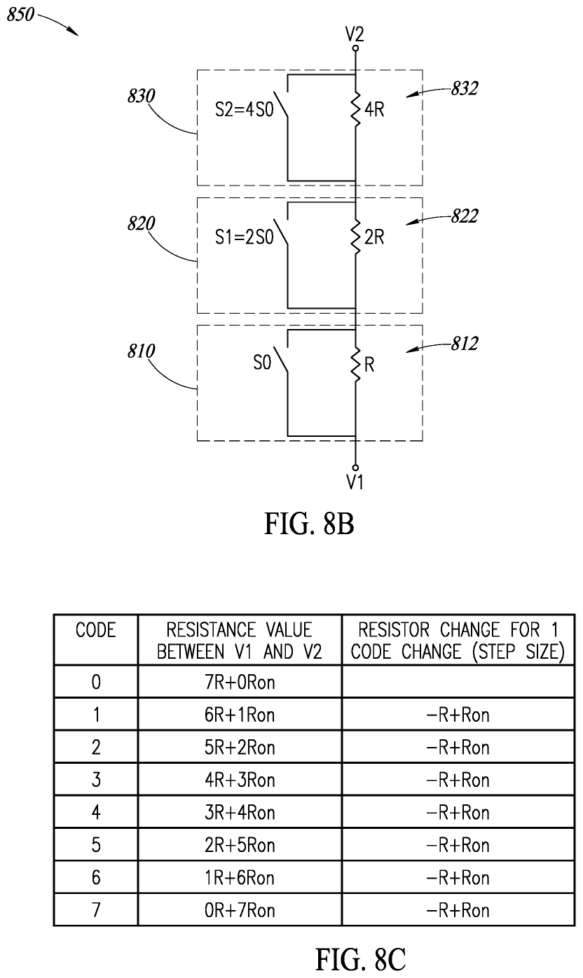

The example embodiment of an N-bit digitally controlled resistor 100 uses a differential architecture to achieve linearity in a digital resistor. The example N-bit digitally controlled resistor overcomes the need for the switch scaling to make the system incorporating the digital resistor linear. In addition, the number of switches needed in the example architecture is smaller than the number of switches needed in some other approaches (see FIGS. 8A-8C). For example, the example N-bit digitally controlled resistor uses 2*N number of switches (where N is the number of bits). Each of the switch-resistor segment includes 2 switches (i.e., a complement switch coupled in series to the resistor and a switch coupled parallel to the complement switch and the resistor). However, while the example N-bit digitally controlled resistor uses 2*N number of switches, other approaches uses 2N number of switches.

Accordingly, as the number of bits get larger, the benefit of the example embodiment becomes greater. For instance, the example N-bit digitally controlled resistor can save the number of switches thereby saving the area. Moreover, lower area also leads to lower switch leakages (e.g., gate leakage). Finally, lesser number of switches also reduces the layout complexity. A person of ordinary skill in the art would readily appreciate other technical benefits besides the ones listed above.

Further benefit includes that the switches in each stage (or each switch-resistor segment) can be designed independent of the switches used in other stages. This provides great flexibility in circuit design.

Switch resistance (e.g., an ON resistance for each switch; Ron) appears as an offset in the system incorporating the digitally-controlled resistor and no longer impacts the step size and linearity of the digitally-controlled resistor. Thus, there is no need to increase the switch size to lower switch resistance Ron, thereby saving area. This is another benefit of the example N-bit digitally controlled resistor.

FIG. 2A is a schematic circuit diagram of a 3-bit digitally controlled resistor according to some embodiments of the present disclosure. FIG. 2B is a table showing a resistance value between a first node and a second node of a 3-bit digitally controlled resistor and a resistor change for one code change according to some embodiments of the present disclosure.

3 bit may be expressed as (S2,S1,S0) where this can include (000), (001), (010), (011), (100), (101), and (111). That is, (100) means that S2 is 1, 51 is 0, and S0 is 0. As previously mentioned, the logic value ‘0’ is indicative of an OFF of a switch and logic value ‘1’ is indicative of an ON of a switch. For (100) which is equal to code 4 in FIG. 2B, this means that switch S2 is ON, switch S1 is OFF, switch S0 is OFF. Respective complement switch operates oppositely. That is, complement switch S2′ is OFF, complement switch S1′ is ON, complement switch S0′ is ON. Accordingly, the resistance between the first node V1 and the second node V2 for code 4 or (100) is 3R+Ron2+Ron1+Ron0. Here, Ron0 is the resistance value across switch S0 (namely, switch resistance), Ron1 is the resistance value across switch S1, and Ron2 is the resistance value across switch S2. In some embodiments where the same type of switches are utilized, each of the resistance value across the switches may be substantially equal to each other. In these cases, Ron0, Ron1, Ron2 may all have the same or substantially the same value.

Referring to FIG. 2B, for code 0 or (S2,S1,S0)=(000), the resistance value between the first node V1 and the second node V2 sums as 7*R+(Ron0+Ron1+Ron2). Similarly, for code 1 or (S2,S1,S0)=(001), the resistance value between the first node V1 and the second node V2 sums as 6*R+(Ron0+Ron1+Ron2). For code 2 or (S2,S1,S0)=(010), the resistance value between the first node V1 and the second node V2 sums as 5*R+(Ron0+Ron1+Ron2). For code 3 or (S2,S1,S0)=(011), the resistance value between the first node V1 and the second node V2 sums as 4*R+(Ron0+Ron1+Ron2). For code 4 or (S2,S1,S0)=(100), the resistance value between the first node V1 and the second node V2 sums as 3*R+(Ron0+Ron1+Ron2). For code 5 or (S2,S1,S0)=(101), the resistance value between the first node V1 and the second node V2 sums as 2*R+(Ron0+Ron1+Ron2). For code 6 or (S2,S1,S0)=(110), the resistance value between the first node V1 and the second node V2 sums as 1*R+(Ron0+Ron1+Ron2). Finally, for code 7 or (S2,S1,S0)=(111), the resistance value between the first node V1 and the second node V2 sums as 0*R+(Ron0+Ron1+Ron2).

A step size is defined as 1 code change, and the resistance value change for 1 code change is calculated as —R. That is, the resistance value change for 1 code change is maintained constant. Here, 1 code change or the step size is independent of Ron0 (ON resistance for switch S0), Ron1 (ON resistance for switch S1), and Ron2 (ON resistance for switch S2). According to the example 3-bit digitally controlled resistor, a switch resistance Ron appears as an offset.

On the other hand, FIGS. 8A-8C illustrate an example approach different from those shown in FIGS. 1, 2A, and 2B. The example of FIGS. 8A-8C are discussed to show the technical benefits of the embodiments of FIGS. 1, 2A, and 2B.

In FIG. 8A, a digital resistor 800 includes a first portion 810, a second portion 820, a third portion 830, . . . and a Nth portion 840 between a first voltage node V1 and a second voltage node V2. The first, second, third, . . . and Nth portions are coupled in series. The first portion 810 includes a switch S0 and a resistor 812 having a resistance value R. The switch S0 is coupled in parallel to the resistor 812. Similarly, the second portion 820 includes a switch S1 and a resistor 822 having a resistance value 2R. The switch S1 is coupled in parallel to the resistor 822. The third portion 830 includes a switch S2 and a resistor 832 having a resistance value 4R. The switch S2 is coupled in parallel to the resistor 832. The Nth portion 840 includes a switch S(N−1) and a resistor 842 having a resistance value 2^{N-1}R. The switch S(N−1) is coupled in parallel to the resistor 842. Here, N is a natural number and is indicative of the number of bits.

Further, while switch S1 is illustrated as being a single switch for simplicity, in an actual implementation, switch S1 has two times the number of switch S0 in series. Similarly, switch S2 has 4 times the number of switch S0 in series, and S(N−1) has 2′ times the number of switch S0 in series. As can be appreciated, according to the example digital resistor shown in FIG. 8A, the number of switches required increases significantly.

FIG. 8B illustrates a 3-bit digital resistor 850 and FIG. 8C illustrates a resistance value between a first voltage node and a second voltage node of the example digital resistor and a resistor change for 1 code change in the same example digital resistor.

Referring to FIG. 8C, for code 0 or (S2,S1,S0)=(000), the resistance value between the first voltage node V1 and the second voltage node V2 sums as 7*R+0*Ron. Similarly, for code 1 or (S2,S1,S0)=(001), the resistance value between the first voltage node V1 and the second voltage node V2 sums as 6*R+1*Ron. For code 2 or (S2,S1,S0)=(010), the resistance value between the first voltage node V1 and the second voltage node V2 sums as 5*R+2*Ron. For code 3 or (S2,S1,S0)=(011), the resistance value between the first voltage node V1 and the second voltage node V2 sums as 4*R+3*Ron. For code 4 or (S2,S1,S0)=(100), the resistance value between the first voltage node V1 and the second voltage node V2 sums as 3*R+4*Ron. For code 5 or (S2,S1,S0)=(101), the resistance value between the first voltage node V1 and the second voltage node V2 sums as 2*R+5*Ron. For code 6 or (S2,S1,S0)=(110), the resistance value between the first voltage node V1 and the second voltage node V2 sums as 1*R+6*Ron. Finally, for code 7 or (S2,S1,S0)=(111), the resistance value between the first voltage node V1 and the second voltage node V2 sums as 0*R+7*Ron. Here, Ron is the ON resistance of switch S0. The resistor change for 1 code change can be represented as −R+Ron as shown in FIG. 8C. However, the example approach of a digital resistor of FIG. 8B shows the dependence of 1 code change (or step size) on Ron.

Referring to FIG. 2B, the resistor change according to the 3-bit digitally controlled resistor of FIG. 2A was —R that is independent of the ON resistance for each switch (i.e., Ron). Having the switch resistance Ron appears as an offset is also beneficial in designing a digitally controlled resistor having linearity. Further, according to other example approaches including the example approach shown in FIGS. 8A-8C, it is shown that the change in resistance is dependent on Ron for 1 code change which entails scaling the switch area to achieve linearity. That is, it is shown that the change in resistance is dependent on Ron value which necessitates the need to scale switch area for improved linearity. The N-bit digitally controlled resistor according to the present disclosure solves the non-linearity problem.

Digitally-Controlled Resistors like the example shown in FIG. 1 find multiple applications including frequency trimming in oscillators. There is a benefit for these systems incorporating the digitally-controlled resistors to be linear and at the same time area efficient. The example embodiment provided solves both these issues by making the digitally-controlled resistor step size independent of the switch resistance and eliminating the need to scale the switch area for linearity. Other application includes, but are not limited to, digitally-controlled resistors, digital potentiometers, resistor DAC, oscillators, and the like.

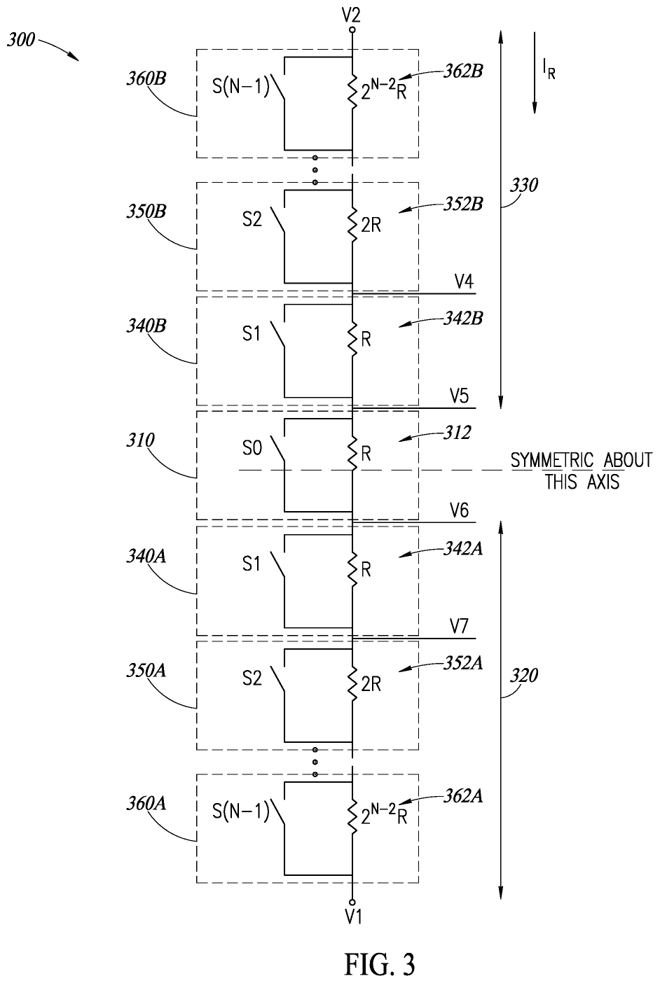

FIG. 3 is a schematic circuit diagram of an N-bit digitally controlled resistor according to another embodiment of the present disclosure.

As shown, each switch-resistor segment has been split into equal halves and have been placed in a symmetric way around the center to get cancellation of impacts of voltage (e.g., V_{GS}) changes across the switches (e.g., S0, S1, S2, . . . ). See, for example, switch-resistor segment 340 which is split into switch-resistor segment 340A and switch-resistor segment 340B with respect to a center axis (which may also be referred to as “imaginary central axis”). As illustrated, the center axis runs in the middle of switch-resistor segment 310. FIG. 7 illustrates one embodiment of a switch included in the switch-resistor segment. The example switch shown in FIG. 7 may be also used for those switches shown throughout the present disclosure including FIGS. 1, 2A, and 2B. A person of ordinary skill in the art would appreciate that other types of switches may be incorporated. Here, voltage V_{GS} indicates the voltage difference between the gate electrode and the source electrode of a transistor.

The example configuration of the N-bit digitally controlled resistor improves the linearity of a system including the N-bit digitally controlled resistor in circumstances dealing with low currents and high resolutions.

The example embodiment of the N-bit digitally controlled resistor cancels or decreases the changes in V_{GS} of the switches and any further impact due to this change such as change in gate leakage due to the change in the digital code (e.g., code change from 0111 to 1000). As the number of bits increase, the advantage of the example configuration becomes more significant.

Referring back to FIG. 3, an N-bit digitally controlled resistor 300 is shown in FIG. 3. The N-bit digitally controlled resistor 300 includes a first node V1, a second node V2, and one or more switch-resistor segments between the first node V1 and the second node V2. Unlike the N-bit digitally controlled resistor 100 as shown in FIG. 1, in FIG. 3 there is no complement switch coupled in series with a resistor for each switch-resistor segment. Further, while the resistance value for each resistor in each respective switch-resistor segment increases by a power of 2 (e.g., 2^{N-1}) from the first node V1 to the second node V2 in FIG. 1, according to FIG. 3, the resistance value for each resistor in respective switch-resistor segment increases by a power of 2 (e.g., 2^{N-1}) from the center (e.g., central switch-resistor segment 310) to the first node V1 and from the center to the second node V2. For example, the resistance value for the second resistor 122 (i.e., 2R) in the second switch-resistor segment 120 is split in half (i.e., R) and each half is arranged symmetrical to the central axis (see switch-resistor segments 340A and 340B). Similarly, the resistance value for the third resistor 132 (i.e., 4R) in the third switch-resistor segment 130 is split in half (i.e., 2R) and each have is arranged symmetrical to the central axis (see switch-resistor segments 350A and 350B).

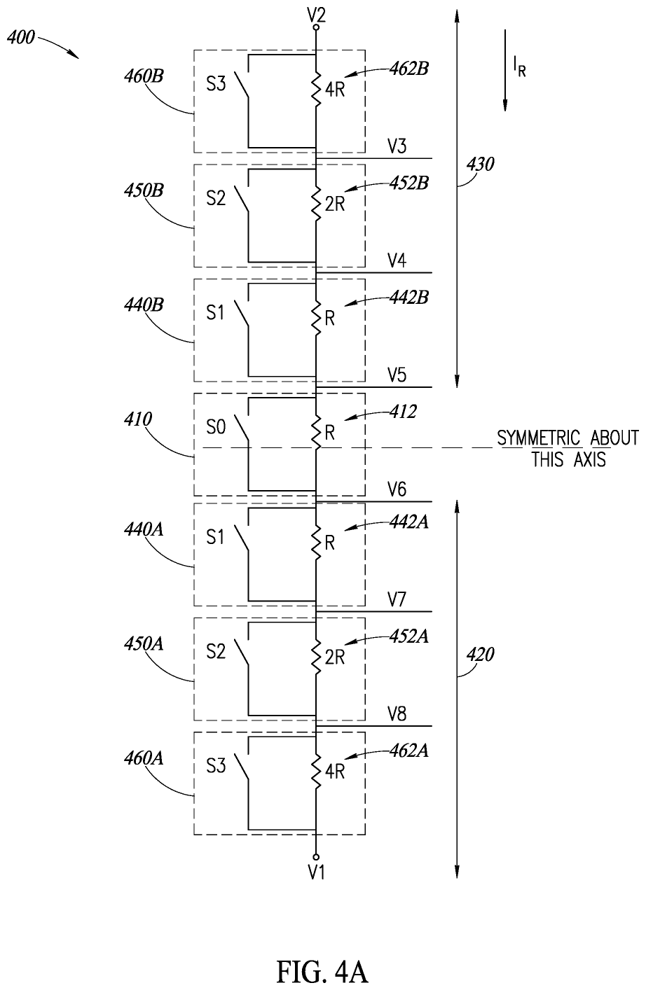

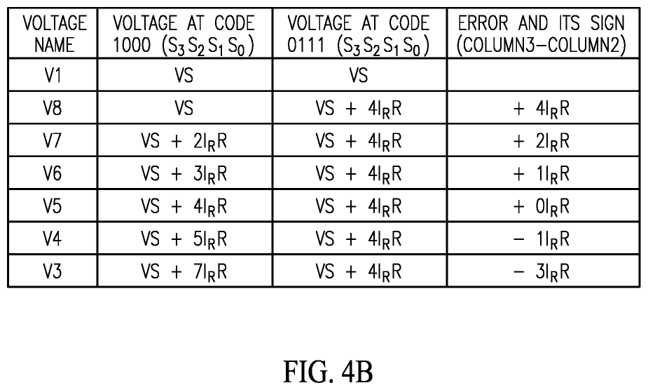

With this example architecture as shown in FIG. 3, the problem of switch leakages degrading the performance of the high resolution digitally-controlled resistor in ultra-low power designs can be addressed. Further, the example architecture enables the code change in the digitally-controlled resistor to give a step size equal to a unit resistance. While change in codes (e.g., 100 to 101) leads to change in the intermediate node voltages, thereby changing the V_{GS} of the switches, and this in turn impacts the leakages of the switches, such leakage problem is reduced or minimized in the example architecture. An error in the step size of the digitally-controlled resistor due to leakage change caused by code change degrades the linearity of the digitally-controlled resistor. However, such problem is resolved in the example embodiment shown in FIG. 3. Other example embodiments shown in FIGS. 4A, 5, and 6A also resolves one or more technical problems in the related art as well as those problems identified above.

Referring back to FIG. 3, the N-bit digitally controlled resistor 300 includes a central switch-resistor segment 310 between the first node V1 and the second node V2. The central switch-resistor segment 310 includes a first resistor 312 having a first resistance value R and a first switch S0 coupled parallel to the first resistor 312. An imaginary central axis runs through the central switch-resistor segment 310 and the imaginary central axis (shown in dotted lines in FIG. 3) or the central switch-resistor segment 310 becomes the point of symmetry.

In some embodiments, the N-bit digitally controlled resistor 300 includes a symmetrical portion or a substantially symmetrical portion between the first node V1 and the second node V2.

A person of ordinary skill in the art would readily appreciate that the N-bit digitally controlled resistor 300 does not necessarily have to be mirror symmetrical with respect to the imaginary central axis in order to achieve the technical benefits previously explained.

For instance, in some embodiments, the resistance value of the resistor included in each switch-resistor segment may be arranged in a symmetrical manner. That is, if an R resistance value resistor is arranged within switch-resistor segment 340A, a same resistor having the R resistance value may be arranged within switch-resistor segment 340B. Similarly, if a 2R resistance value resistor is arranged within switch-resistor segment 350A, a same resistor having the 2R resistance value may be arranged within switch-resistor segment 350B, and so forth. The same type of switch may be utilized. That is, if switch S1 is used in switch-resistor segment 340A, the same switch S1 is used in switch-resistor segment 340B. Similarly, if switch S2 is used in switch-resistor segment 350A, the same switch S2 is used in switch-resistor segment 350B. However, in some embodiments, the location and position of the switch and resistor does not necessarily have to be strictly symmetrical with respect to the imaginary central axis. Namely, for some embodiments, mirror symmetry is not required.

In the central switch-resistor segment 310, switch S0 is coupled in parallel with resistor 312. Adjacent to the central switch-resistor segment 310 is a lower switch-resistor segment 340A and an upper switch-resistor segment 340B. The term “lower” and “upper” were merely used to indicate that the switch-resistor segment 340A is located below the imaginary central axis and to indicate that the switch-resistor segment 340B is located above the imaginary central axis. The lower switch-resistor segment 340A includes resistor 342A having resistor value R and a switch S1 coupled parallel to the resistor 342A. The upper switch-resistor segment 340B includes resistor 342B having resistor value R and a switch S1 coupled parallel to the resistor 342B. In one embodiment, the resistance value of resistor 312 in the central switch-resistor segment 310 is identical or substantially identical to the resistance value of resistor 342A, 342B.

The central switch-resistor segment 310 is coupled in series and is between the lower switch-resistor segment 340A and the upper switch-resistor segment 340B. A sixth node V6 is between the central switch-resistor segment 310 and the lower switch-resistor segment 340A. To be specific, the sixth node V6 is between resistor 312 and resistor 342A. As shown, a fifth node V5 is between the central switch-resistor segment 310 and the upper switch-resistor segment 340B. To be specific, the fifth node V5 is between resistor 312 and resistor 342B.

Adjacent to the lower switch-resistor segment 340A is a lower switch-resistor segment 350A. On the other side, the upper switch-resistor segment 340B is adjacent to an upper switch-resistor segment 350B. The lower switch-resistor segment 350A includes resistor 352A having resistor value 2R and a switch S2 coupled parallel to the resistor 352A. The upper switch-resistor segment 350B includes resistor 352B having resistor value 2R and a switch S2 coupled parallel to the resistor 352B. A seventh node V7 is between the lower switch-resistor segment 350A and the lower switch-resistor segment 340A. In particular, the seventh node V7 is between resistor 352A and resistor 342A. As shown, a fourth node V4 is between the upper switch-resistor segment 350B and the upper switch-resistor segment 340B. In particular, the fourth node V4 is between resistor 352B and resistor 342B.

Depending on the number of N bits, there may be (N−1) number of switch-resistor segments on a lower section 320 and (N−1) number segments on an upper section 330. The lower section 320 and the upper section 330 do not include the central switch-resistor segment 310.

A lower switch-resistor segment 360A includes resistor 362A having resistor value 2^{N-2}R and a switch S(N−1) coupled parallel to the resistor 362A. An upper switch-resistor segment 360B includes resistor 362B having resistor value 2^{N-2}R and a switch S(N−1) coupled parallel to the resistor 362B.

A method of operating an N-bit digitally controlled resistor 300 according to FIG. 3 is also provided. The method includes controlling a first switch S0 of a central switch-resistor segment 310 coupled in parallel with a first resistor 312 having a first resistance value R based on a digital bit between a ‘0’ logic value and a ‘1’ logic value. Controlling the first switch S0 of the central switch-resistor segment 310 includes turning on the first switch S0 based on a digital bit of ‘1’ logic value and/or turning off the first switch S0 based on a digital bit of ‘0’ logic value. Controlling the first switch S0 of the central switch-resistor segment 310 is indicative of a least significant bit (LSB) of the N-bit digitally controlled resistor 300.

The method also includes controlling a second switch S1 of a second switch-resistor segment coupled 340A, 340B based on the digital bit between a ‘0’ logic value and a ‘1’ logic value. Controlling the second switch S1 of the second switch-resistor segment 340A, 340B includes turning on the second switch S1 based on the digital bit of ‘1’ logic value and/or turning off the second switch S1 based on the digital bit of ‘0’ logic value.

In one embodiment, controlling the second switch S1 of the second switch-resistor segment 340A is done simultaneously with controlling the second switch S1 of the second switch-resistor segment 340B.

Controlling the second switch S1 is indicative of a next highest bit adjacent to the LSB of the N-bit digitally controlled resistor 300.

When the digitally controller resistor is an N-bit digital resistor 300 as shown in FIG. 3, the method includes controlling a Nth switch S(N−1) of a Nth switch-resistor segment 360A, 360B coupled in parallel with a Nth resistor 362A, 362B having a resistance value 2^{N-2} times the first resistance value R based on the digital bit between a ‘0’ logic value and a ‘1’ logic value. Controlling the Nth switch of the Nth switch-resistor segment includes turning on and off the Nth switch based on the digital bit.

A current I_{R} flows between the first node V1 and the second node V2. The structural benefit of the configuration shown in FIG. 3 will be further explained in conjunction with FIG. 4A which shows an example of a 4-bit digitally controlled resistor.

FIG. 4A is an example of a 4-bit digitally controlled resistor. FIG. 4B is a table showing an error when code changes from 1000 to 0111 or vice versa.

The 4-bit digitally controlled resistor 400 includes various switch-resistor segments 440A, 440B, 450A, 450B, 460A, 460B and central switch-resistor segment 410. A person of ordinary skill in the art would appreciate the 4-bit digitally controlled resistor 400 shown in FIG. 4A has the same structure as FIG. 3 when N is 4. Accordingly, redundant explanation of the circuit architecture will be omitted.

As shown, switch-resistor segment 440 has been split into equal halves and have been placed in a symmetric way with respect to a central switch-resistor segment 410. That is, switch-resistor segment 440A is placed on a first side 420 adjacent to the central switch-resistor segment 410 and switch-resistor segment 440B is placed on a second side 420 adjacent to the central switch-resistor segment 410. Similarly, switch-resistor segment 450 has been split into equal halves and have been placed in a symmetric way with respect to a central switch-resistor segment 410. That is, switch-resistor segment 450A is placed on the first side 420 adjacent to the switch-resistor segment 440A and switch-resistor segment 450B is placed on the second side 420 adjacent to the switch-resistor segment 440B. In addition, switch-resistor segment 460 has been split into equal halves and have been placed in a symmetric way with respect to a central switch-resistor segment 410. That is, switch-resistor segment 460A is placed on the first side 420 adjacent to the switch-resistor segment 450A and switch-resistor segment 460B is placed on the second side 420 adjacent to the switch-resistor segment 450B.

The switch-resistor segments have been split into equal halves and have been placed in a symmetric way around the center to get cancellation of impacts of voltage (e.g., V_{GS}) changes across the switches (e.g., S0, S1, S2, . . . ). The example configuration of the 4-bit digitally controlled resistor improves the linearity of a system including the 4-bit digitally controlled resistor in circumstances dealing with low currents and high resolutions. The example embodiment of the 4-bit digitally controlled resistor cancels or decreases the changes in V_{GS} of the switches and any further impact due to this change such as change in gate leakage due to the change in the digital code (e.g., code change from 0111 to 1000). As the number of bits increase, the advantage of the example configuration becomes more significant.

Referring to FIG. 4B, 4-bit may be expressed as (S3,S2,S1,S0) where this can include (0000), (0001), (0010), (0011), . . . and (1111). That is, (1000) means that S3 is 1, S2 is 0, S1 is 0, and S0 is 0. As previously mentioned, the logic value ‘0’ is indicative of an OFF of a switch and logic value ‘1’ is indicative of an ON of a switch. For code (1000), this means that switch S3 is ON, S2 is OFF, switch S1 is OFF, and switch S0 is OFF. On the other hand, (0111) means that S3 is 0, S2 is 1, S1 is 1, and S0 is 1. For code (0111), this means that switch S3 is OFF, S2 is ON, switch S1 is ON, and switch S0 is ON. An example code change from (1000) to (0111) is used as error is maximum when code is changed from (1000) to (0111).

Here, voltage of the first node V1 is equal to VS and current I_{R} flows into the second node V2. Also, for the purpose of illustration, switch resistance Ron is assumed to be negligible. Based on this, the calculation is provided as shown in the table of FIG. 4B

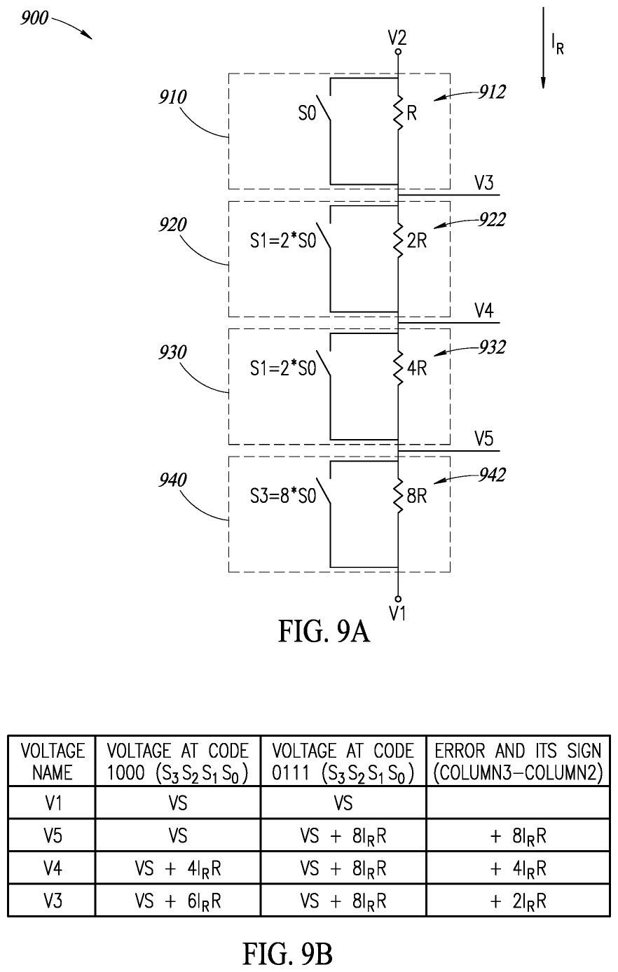

From the table, the V_{GS} for the switches change in both direction, thereby cancelling the errors to significant extent. The sum of the error can be calculated based on adding the difference of ‘voltage at code 1000’ (column 2) with ‘voltage at code 0111’ (column 3) as shown in column 4: 0+4*I_{R}R+2*I_{R}R+1*I_{R}R+0*I_{R}R+(−1)*I_{R}R+(−3)*I_{R}R. That is, error for the present example is 3*IRR (this is smaller than the error created based on the approaches shown in FIG. 9A which is 14*IRR). Accordingly, the example embodiment according to FIGS. 3 and 4A improves the linearity or the step size in a digital resistor. Further, the impact of V_{GS} change on R_{ON} will also be cancelled in a similar manner. A person of ordinary skill in the art will appreciate that as the number of bits increase, the advantage of the example architecture becomes more significant. Further, an error due to switch V_{GS} change for N-bit digital resistor at major code change can be represented as (N−1)*I_{R}R. The N-bit digital resistor approach based on FIG. 9A has an error of (2^{N}−2)*I_{R}R at major code changes. That is, the example architecture using symmetry can reduce the error from exponential to linear.

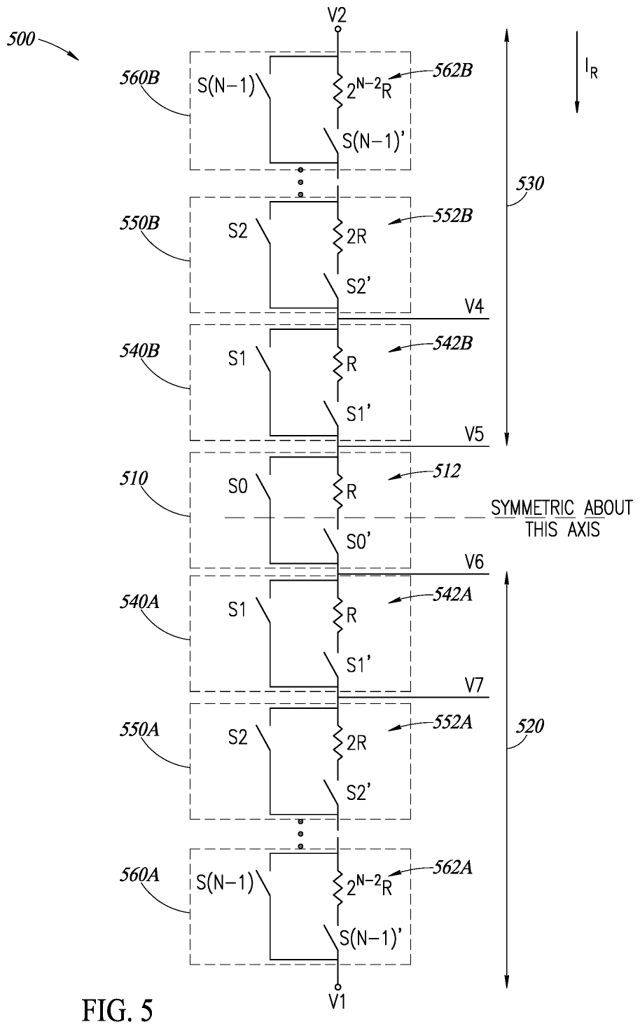

FIG. 5 is a schematic circuit diagram of an N-bit digitally controlled resistor according to yet another embodiment of the present disclosure.

The N-bit digitally controlled resistor 500 is same or similar to the N-bit digitally controlled resistor 300 of FIG. 3 except that each switch-resistor segment includes a complement switch coupled in series with a resistor within respective switch-resistor segment.

As shown, each switch-resistor segments (except for the central switch-resistor segment 510) have been split into equal halves and have been placed in a symmetric way around the central switch-resistor segment 510 to get cancellation of impacts of voltage (e.g., V_{GS}) changes across the switches (e.g., S0, S1, S2, . . . ). See, for example, switch-resistor segment 540 which is split into switch-resistor segment 540A and switch-resistor segment 540B with respect to a center axis (which may also be referred to as “imaginary central axis”) or with respect to the central switch-resistor segment 510. As illustrated, the center axis runs in the middle of the central switch-resistor segment 510.

The example configuration of the N-bit digitally controlled resistor 500 improves the linearity of a system including the N-bit digitally controlled resistor in circumstances dealing with low currents and high resolutions.

The example embodiment of the N-bit digitally controlled resistor cancels or decreases the changes in V_{GS} of the switches and any further impact due to this change such as change in gate leakage due to the change in the digital code (e.g., code change from 0111 to 1000 or from 1000 to 0111). As the number of bits increase, the advantage of the example configuration becomes more significant.

Referring back to FIG. 5, an N-bit digitally controlled resistor 500 includes a first node V1, a second node V2, and one or more switch-resistor segments between the first node V1 and the second node V2. Unlike the N-bit digitally controlled resistor 300 as shown in FIG. 3, in FIG. 5, there a complement switch coupled in series with a resistor for each switch-resistor segment (see. S1′, S2′, . . . S(N−1)′). Further, while the resistance value for each resistor in respective switch-resistor segment increases by a power of 2 (e.g., 2^{N-1}) from the first node V1 to the second node V2 in FIG. 1, according to FIG. 5, the resistance value for each resistor in respective switch-resistor segment increases by a power of 2 (e.g., 2N−1) from the center (e.g., central switch-resistor segment 510) to the first node V1 and from the center to the second node V2. For example, the resistance value for resistor 542A (i.e., R) in the switch-resistor segment 540A increases in the power of 2 as it approaches further away from the center axis and closer to the first node V1. Similarly, the resistance value for resistor 542B (i.e., R) in the switch-resistor segment 540B increases in the power of 2 as it approaches further away from the center axis and closer to the second node V2.

The example architecture as shown in FIG. 5, also solves the various technical problems previously explained in conjunction to FIGS. 1 and 3.

As shown in FIG. 5, the N-bit digitally controlled resistor 500 includes a central switch-resistor segment 510 between the first node V1 and the second node V2. The central switch-resistor segment 510 includes a first resistor 512 having a first resistance value R, a first complement switch S0′ coupled in series with the first resistor 512, and a first switch S0 coupled parallel to the first resistor 512 and the first complement switch S0′. An imaginary central axis runs through the central switch-resistor segment 510 and the imaginary central axis (shown in dotted lines in FIG. 5) or the central switch-resistor segment 510 becomes the point of symmetry.

In some embodiments, the N-bit digitally controlled resistor 500 includes a symmetrical portion or a substantially symmetrical portion between the first node V1 and the second node V2.

A person of ordinary skill in the art would readily appreciate that the N-bit digitally controlled resistor 500 does not necessarily have to be mirror symmetrical with respect to the imaginary central axis in order to achieve the technical benefits previously explained and thus the digital resistor 500 may only require substantial symmetry to achieve the aforementioned technical benefits.

For instance, in some embodiments, the resistance value of the resistor included in each switch-resistor segment may be arranged in a symmetrical manner. That is, if an R resistance value resistor is arranged within switch-resistor segment 540A, a same resistor having the R resistance value may be arranged within switch-resistor segment 540B. Similarly, if a 2R resistance value resistor is arranged within switch-resistor segment 550A, a same resistor having the 2R resistance value may be arranged within switch-resistor segment 550B, and so forth. The same type of switch may be utilized and arranged in a symmetrical manner. That is, if switch S1 is used in switch-resistor segment 540A, the same switch S1 is used in switch-resistor segment 540B. Similarly, if switch S2 is used in switch-resistor segment 550A, the same switch S2 is used in switch-resistor segment 550B. However, in some embodiments, the location and position of the switch and resistor does not necessarily have to be strictly symmetrical with respect to the imaginary central axis. Namely, for some embodiments, mirror symmetry is not required. That is, even if the location of switch S1 in switch-resistor segment 540A slightly deviates from the exact opposite location of switch S1 in switch-resistor segment 540B with respect to the imaginary central axis, the example embodiment of the digital resistor 500 would still be able to achieve the aforementioned technical benefits.

In the central switch-resistor segment 510, switch S0 is coupled in parallel with resistor 512. Adjacent to the central switch-resistor segment 510 is a lower switch-resistor segment 540A and an upper switch-resistor segment 540B. As mentioned previously, the term “lower” and “upper” were merely used to indicate that the switch-resistor segment 540A is located below the imaginary central axis and to indicate that the switch-resistor segment 540B is located above the imaginary central axis. The lower switch-resistor segment 540A includes resistor 542A having resistor value R, a complement switch S1′ coupled in series with resistor 542A, and a switch S1 coupled parallel to the resistor 542A and the complement switch S1′. The upper switch-resistor segment 540B includes resistor 542B having resistor value R, a complement switch S1′ coupled in series with resistor 542B, and a switch S1 coupled parallel to the resistor 542B and the complement switch S1′. In one embodiment, the resistance value of resistor 512 in the central switch-resistor segment 510 is identical or substantially identical to the resistance value of resistor 542A, 542B.

The central switch-resistor segment 510 is coupled in series and is between the lower switch-resistor segment 540A and the upper switch-resistor segment 540B. A sixth node V6 is between the central switch-resistor segment 510 and the lower switch-resistor segment 540A. To be specific, the sixth node V6 is between complement switch S0′ and resistor 542A. As shown, a fifth node V5 is between the central switch-resistor segment 510 and the upper switch-resistor segment 540B. To be specific, the fifth node V5 is between resistor 512 and complement switch S1′.

Adjacent to the lower switch-resistor segment 540A is a lower switch-resistor segment 550A. On the other side, the upper switch-resistor segment 540B is adjacent to an upper switch-resistor segment 550B. The lower switch-resistor segment 550A includes resistor 552A having resistor value 2R, a complement switch S2′ coupled in series with resistor 552A, and a switch S2 coupled parallel to the resistor 552A and the complement switch S2′. The upper switch-resistor segment 550B includes resistor 552B having resistor value 2R, a complement switch S2′ coupled in series with resistor 552B, and a switch S2 coupled parallel to the resistor 552B and the complement switch S2′. A seventh node V7 is between the lower switch-resistor segment 350A and the lower switch-resistor segment 540A. To be specific, the seventh node V7 is between resistor 552A and complement switch S1′. As shown, a fourth node V4 is between the upper switch-resistor segment 550B and the upper switch-resistor segment 540B. To be specific, the fourth node V4 is between complement switch S2′ and resistor 542B.

Depending on the number of N bits, there may be (N−1) number of switch-resistor segments on a lower section 520 and (N−1) number segments on an upper section 530. The lower section 520 and the upper section 530 does not include the central switch-resistor segment 510.

A lower switch-resistor segment 560A includes resistor 562A having resistor value 2^{N-2}R, a complement switch S(N−1)′ coupled in series with resistor 562A, a switch S(N−1) coupled parallel to the resistor 562A and the complement switch S(N−1)′. An upper switch-resistor segment 560B includes resistor 562B having resistor value 2^{N-2}R, a complement switch S(N−1)′ coupled in series with resistor 562B, and a switch S(N−1) coupled parallel to the resistor 562B and the complement switch S(N−1)′. Here, N may be a natural number greater than or equal to 2. For example, when the bit number is 2 bits (when N equals to 2), there will be a switch-resistor segment 540 (including both switch-resistor segment 540A and switch-resistor segment 540B) and a central switch-resistor segment 510 between the first node V1 and the second node V2. When the bit number is 3 bits (when N equals to 3), there will be a switch-resistor segment 540 (including both switch-resistor segment 540A and switch-resistor segment 540B), a switch-resistor segment 550 (including both switch-resistor segment 550A and switch-resistor segment 550B), and a central switch-resistor segment 510 between the first node V1 and the second node V2.

A method of operating an N-bit digitally controlled resistor 500 according to FIG. 5 is also provided. The method includes controlling a first switch S0 of a central switch-resistor segment 510 based on a digital bit between a ‘0’ logic value and a ‘1’ logic value. The first switch S0 is coupled in parallel with a first resistor 512 and a first complement switch S0′ of the central switch-resistor segment 510. The first resistor 512 has a first resistance value R. The first complement switch S0′ is coupled in series with the first resistor 512.

The method includes controlling the first complement switch S0′ in response to the digital bit provided to the first switch S0. Controlling the first switch S0 and the first complement switch S0′ of the central switch-resistor segment 510 includes turning on the first switch based on a digital bit of ‘1’ logic value and turning off the first complement switch and/or turning off the first switch based on a digital bit of ‘0’ logic value and turning on the first complement switch.

Controlling the first switch of the central switch-resistor segment is indicative of a LSB of the N-bit digitally controlled resistor 500.

As shown a second switch-resistor segment 540A and 540B is coupled adjacent to the central switch-resistor segment 510 to have symmetry with respect to the imaginary central axis (see dotted line).

Here, the method includes controlling a second switch S1 of a second switch-resistor segment 540A, 540B based on the digital bit between a ‘0’ logic value and a ‘1’ logic value. The second switch S1 is coupled in parallel with a second resistor 542A, 542B a second complement switch S1′ of the second switch-resistor segment 540A, 540B. The second resistor 542A, 542B has the first resistance value R.

The method includes controlling the second complement switch in response to the digital bit provided to the second switch. Controlling the second switch and the second complement switch of the second switch-resistor segment includes turning on the second switch based on the digital bit of ‘1’ logic value and turning off the second complement switch and/or turning off the second switch based on the digital bit of ‘0’ logic value and turning on the second complement switch.

In one embodiment, controlling the second switch S1 of the second switch-resistor segment 540A is done simultaneously with controlling the second switch S1 of the second switch-resistor segment 540B.

Controlling the second switch is indicative of a next highest bit adjacent to the LSB of the N-bit digitally controlled resistor 500.

When the digitally controller resistor is an N-bit digital resistor 500 as shown in FIG. 5, the method includes controlling a Nth switch S(N−1) of a Nth switch-resistor-segment based on a digital bit between a ‘0’ logic value and a ‘1’ logic value. The Nth switch S(N−1) is coupled in parallel with a Nth resistor 562A, 562B and a Nth complement switch S(N−1)′ of a Nth switch-resistor segment 560A, 560B. The Nth resistor 562A, 562B has a resistance value 2^{N-2} times the first resistance value R. The Nth complement switch S(N−1)′ is coupled in series with the Nth resistor 562A, 562B.

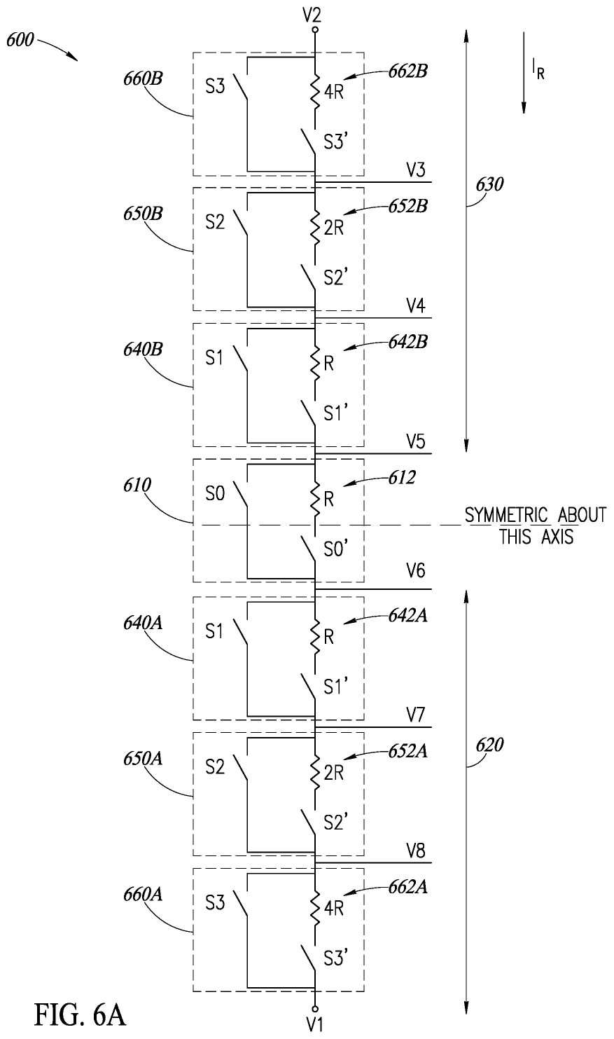

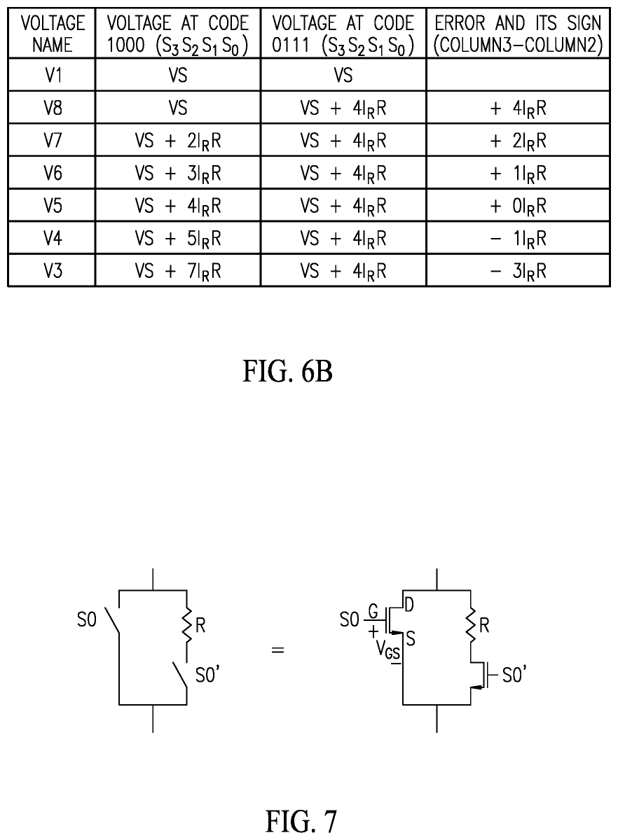

The method includes controlling the Nth complement switch in response to the digital bit provided to the Nth switch. Controlling the Nth switch and the Nth complement switch of the Nth switch-resistor segment includes turning on the Nth switch based on the digital bit of ‘1’ logic value and turning off the Nth complement switch and/or turning off the Nth switch based on the digital bit of ‘0’ logic value and turning on the Nth complement switch. A current I_{R} flows between the first node V1 and the second node V2. The structural benefit of the configuration shown in FIG. 5 will be further explained in conjunction with FIG. 6A which shows an example of a 4-bit digitally controlled resistor.

FIG. 6A is an example of a 4-bit digitally controlled resistor. FIG. 6B is a table showing error when code changes from 1000 to 0111 or vice versa.

The 4-bit digitally controlled resistor 600 includes various switch-resistor segments 640A, 640B, 650A, 650B, 660A, 660B and central switch-resistor segment 610. A person of ordinary skill in the art would appreciate the 4-bit digitally controlled resistor 600 shown in FIG. 6A has the same structure as FIG. 5 when N is 4. Accordingly, redundant explanation of the circuit architecture will be omitted.

Referring to FIG. 6B, 4-bit may be expressed as (S3,S2,S1,S0) where this can include (0000), (0001), (0010), (0011), . . . and (1111). That is, (1000) means that S3 is 1, S2 is 0, S1 is 0, and S0 is 0. As previously mentioned, the logic value ‘0’ is indicative of an OFF of a switch and logic value ‘1’ is indicative of an ON of a switch. For code (1000), this means that switch S3 is ON, S2 is OFF, switch S1 is OFF, and switch S0 is OFF. On the other hand, (0111) means that S3 is 0, S2 is 1, S1 is 1, and S0 is 1. For code (0111), this means that switch S3 is OFF, S2 is ON, switch S1 is ON, and switch S0 is ON. An example code change from (1000) to (0111) (or vice versa) is used as error is maximum when code is changed from (1000) to (0111) (or vice versa).

Here, voltage of the first node V1 is equal to VS and current I_{R} flows into the second node V2. Also, for the purpose of illustration, switch resistance Ron is assumed to be negligible. Based on this, the calculation is provided as shown in the table of FIG. 6B.

From the table, the V_{GS} for the switches change in both directions, thereby cancelling the errors to significant extent. The sum of the error can be calculated based on adding the difference of ‘voltage at code 1000’ (column 2) with ‘voltage at code 0111’ (column 3) as shown in column 4: 0+4*I_{R}R+2*I_{R}R+1*I_{R}R+0*I_{R}R+(−1)*I_{R}R+(−3)*I_{R}R. That is, error for the present example is 3*I_{R}R (this is smaller than the error created based on the approaches shown in FIG. 9A which is 14*I_{R}R). Accordingly, the example embodiment according to FIGS. 5 and 6A improves the linearity or the step size in a digital resistor. Further, the impact of V_{GS} change on R_{ON} will also be cancelled in a similar manner. A person of ordinary skill in the art will appreciate that as the number of bits increase, the advantage of the example architecture becomes more significant. Further, an error due to switch V_{GS} change for N-bit digital resistor at major code change can be represented as (N−1)*I_{R}R. The N-bit digital resistor approach based on FIG. 9A has an error of (2^{N}−2)*I_{R}R at major code changes. That is, the example architecture using symmetry can reduce the error from exponential to linear.

To further elaborate the technical benefit of the example structures discussed in conjunction with FIGS. 3, 4A, 5, and 6A, another example approach is explained in conjunction with FIGS. 9A and 9B.

FIGS. 9A and 9B illustrate an example approach different from those shown in FIGS. 3, 4A, 5, and 6A. The example of FIGS. 9A and 9B are discussed to show the technical benefits of the embodiments of FIGS. 3, 4A, 5, and 6A.

In FIG. 9A, a 4-bit digital resistor 900 includes a first portion 910, a second portion 920, a third portion 930, and a fourth portion 940 between a first voltage node V1 and a second voltage node V2. The first, second, third, and fourth portions are coupled in series. The first portion 910 includes a switch S0 and a resistor 912 having a resistance value R. The switch S0 is coupled in parallel to the resistor 912. Similarly, the second portion 920 includes a switch S1 and a resistor 922 having a resistance value 2¹R. The switch S1 is coupled in parallel to the resistor 922. The third portion 930 includes a switch S2 and a resistor 932 having a resistance value 2²R. The switch S2 is coupled in parallel to the resistor 932. The fourth portion 940 includes a switch S3 and a resistor 942 having a resistance value 2³R. The switch S3 is coupled in parallel to the resistor 942. Here, N is a natural number and is indicative of the number of bits.

Further, while switch S1 is illustrated as being a single switch for simplicity, in an actual implementation, switch S1 has 2 times the number of switch S0 (that is, two switch S0 switches connected in series). Similarly, switch S2 has 4 times the number of switch S0 (that is, four switch S0 switches connected in series), and S3 has 8 times the number of switch S0 (that is, eight switch S0 switches connected in series). As can be appreciated, according to the example digital resistor shown in FIG. 9A, the number of switches required increases significantly in an exponential manner (e.g., power of 2).

FIG. 9B illustrates an error at each of the voltage nodes within the example digital resistor when a code changes from (1000) to (0111) (or vice versa). This example is used as error is maximum when code is changed from (1000) to (0111) (or vice versa).

Referring to FIG. 9B, here, voltage of the first node V1 is equal to VS and current I_{R} flows into the second node V2. Also, for the purpose of illustration, switch resistance Ron is assumed to be negligible. Based on this, the calculation is provided as shown in the table of FIG. 9B.

For example, the voltage read at a first voltage node V1 equals to VS when code is (S3,S2,S1,S0)=(1000) and when code is (0111). The voltage read at a fifth voltage node V5 equals to VS when code is (1000) and VS+8*I_{R}R when code is (0111). The voltage read at a fourth voltage node V4 equals to VS+4*I_{R}R when code is (1000) and VS+8*I_{R}R when code is (0111). The voltage read at a third voltage node V3 equals to VS+6*I_{R}R when code is (1000) and VS+8*I_{R}R when code is (0111).

From the table, the sum of the error can be calculated based on adding the difference of ‘voltage at code 1000’ (column 2) with ‘voltage at code 0111’ (column 3) as shown in column 4: 0+8*I_{R}R+4*I_{R}R+2*I_{R}R. That is, the error for the present example is 14*I_{R}R (this is greater than the error created based on the approaches shown in FIG. 6A which is 3*I_{R}R). Accordingly, the example embodiment according to FIGS. 1, 2A, 3, 4A, 5, 6A improves the linearity or the step size in a digital resistor. Further, the impact of V_{GS} change on R_{ON} will also be cancelled in a similar manner. A person of ordinary skill in the art will appreciate that as the number of bits increase, the advantage of the example architecture becomes more significant. Further, an error due to switch V_{GS} change for N-bit digital resistor at major code change can be represented as (N−1)*I_{R}R. The N-bit digital resistor approach based on FIG. 9A has an error of (2N−2)*I_{R}R at major code changes. That is, the example architecture using symmetry can reduce the error from exponential to linear.

The digitally controlled resistor as described herein may be incorporated within a circuit according to various circuit designs and may also be incorporated within a larger device such as an electronic device.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
a first node and a second node;
a first switch-resistor segment between the first node and the second node, the first switch-resistor segment including:
a first resistor having a first resistance value;
a first complement switch coupled in series with the first resistor; and
a first switch coupled parallel to the first resistor and the first complement switch, the first switch being switched ON when the first complement switch is OFF and the first switch being switched OFF when the first complement switch is ON.

2. The electronic device of claim 1, comprising a N number of switch-resistor segments, each switch-resistor segment coupled between the first node and the second node and including:
a Nth resistor having a resistance value corresponding to the first resistance value multiplied by 2^{N-1};
a Nth complement switch coupled in series with the Nth resistor; and
a Nth switch coupled parallel to the Nth resistor and the Nth complement switch, the Nth switch being switched ON when the Nth complement switch is OFF and the Nth switch being switched OFF when the Nth complement switch is ON, N being a natural number greater than 1.

3. The electronic device of claim 2, wherein N is indicative of a number of bits in an N-bit digitally controlled resistor.

4. The electronic device of claim 3, wherein the (N−1) number of switch-resistor segments are coupled in series with the first switch-resistor segment.

5. The electronic device of claim 4, wherein an ON state and an OFF state of the first switch included in the switch-resistor segment represents a least significant bit (LSB) of the N-bit digitally controlled resistor.

6. The electronic device of claim 4, wherein an ON state and an OFF state of the Nth switch included in a Nth switch-resistor segment represents a most significant bit (MSB) of the N-bit digitally controlled resistor.

7-9. (canceled)

10. An electronic device, comprising:
an N-bit digitally controlled resistor including:
a first node and a second node;
a central switch-resistor segment between the first node and the second node, the central switch-resistor segment including:
a first resistor having a first resistance value; and
a first switch coupled parallel to the first resistor; and
a plurality of switch-resistor segments arranged symmetrically with respect to the central switch-resistor segment, a number of switch-resistor segments among the plurality of switch-resistor segments in a first section between the first node and the central switch-resistor segment and a number of switch-resistor segments among the plurality of switch-resistor segments in a second section between the second node and the central switch-resistor segment being equal to each other.

11. The electronic device of claim 10, a first switch-resistor segment closest to the central switch-resistor segment in the first section among the plurality of switch-resistor segments including:
a second resistor having a second resistance value equal to the first resistance value of the first resistor;
a second switch coupled parallel to the second resistor, and
a second switch-resistor segment closest to the central switch-resistor segment in the second section being symmetrical to the first switch-resistor segment with respect to the central switch-resistor segment, the second switch-resistor segment including a same switch and a same resistor as included in the first switch-resistor segment.

12. The electronic device of claim 11, a Nth switch-resistor segment farthest from the central switch-resistor segment in the first section among the plurality of switch-resistor segments and closest to the first node including:
a Nth resistor having a resistance value equal to the first resistance value of the first resistor multiplied by 2^{N-2}; and
a Nth switch coupled parallel to the Nth resistor, N being a natural number greater than 1,
a third switch-resistor segment closest to the second node in the second section being symmetrical to the Nth switch-resistor segment with respect to the central switch-resistor segment, the third switch-resistor segment including a same switch and a same resistor as included in the Nth switch-resistor segment in the first section.

13. The electronic device of claim 10, wherein an ON state and an OFF state of the first switch included in the central switch-resistor segment represents LSB of the N-bit digitally controlled resistor.

14. The electronic device of claim 12, wherein an ON state and an OFF state of the Nth switch included in the Nth switch-resistor segment represents a MSB of the N-bit digitally controlled resistor.

15-17. (canceled)

18. An electronic device, comprising:
an N-bit digitally controlled resistor including:
a first node and a second node;
a central switch-resistor segment between the first node and the second node, the central switch-resistor segment including:
a first resistor having a first resistance value;
a first complement switch coupled in series with the first resistor; and
a first switch coupled parallel to the first resistor and the first complement switch, the first switch being switched ON when the first complement switch is OFF and the first switch being switched OFF when the first complement switch is ON; and
a plurality of switch-resistor segments arranged symmetrically with respect to the central switch-resistor segment, a number of switch-resistor segments among the plurality of switch-resistor segments in a first section between the first node and the central switch-resistor segment and a number of switch-resistor segments among the plurality of switch-resistor segments in a second section between the second node and the central switch-resistor segment being equal to each other.

19. The electronic device of claim 18, a first switch-resistor segment closest to the central switch-resistor segment in the first section among the plurality of switch-resistor segments including:
a second resistor having a second resistance value equal to the first resistance value of the first resistor;
a second complement switch coupled in series with the second resistor;
a second switch coupled parallel to the second resistor and the second complement switch; and
a second switch-resistor segment closest to the central switch-resistor segment in the second section being symmetrical to the first switch-resistor segment with respect to the central switch-resistor segment, the second switch-resistor segment including a same switch and a same resistor as included in the first switch-resistor segment.

20. The electronic device of claim 19, a Nth switch-resistor segment farthest from the central switch-resistor segment in the first section among the plurality of switch-resistor segments and closest to the first node including:
a Nth resistor having a resistance value equal to the first resistance value of the first resistor multiplied by 2^{N-2};
a Nth complement switch coupled in series with the Nth resistor;
a Nth switch coupled parallel to the Nth resistor and the Nth complement switch, N being a natural number greater than 1; and
a third switch-resistor segment closest to second node in the second section being symmetrical to the Nth switch-resistor segment with respect to the central switch-resistor segment, the third switch-resistor segment including a same switch, a same complement switch, and a same resistor as included in the Nth switch-resistor segment in the first section.

21. The electronic device of claim 18, wherein an ON state and an OFF state of the first switch included in the central switch-resistor segment represents LSB of the N-bit digitally controlled resistor.

22. The electronic device of claim 20, wherein an ON state and an OFF state of the Nth switch included in the Nth switch-resistor segment represents a MSB of the N-bit digitally controlled resistor.

23. The electronic device of claim 20, a Nth switch-resistor segment farthest from the central switch-resistor segment and closest to the first node being symmetrical to the third switch-resistor segment farthest from the central switch-resistor segment and closest to the first node with respect to the central switch-resistor segment, the third switch-resistor segment farthest from the central switch-resistor segment and closest to the second node including a same switch and a same resistor as included in the Nth switch-resistor segment farthest from the central switch-resistor segment and closest to the first node.

24-26. (canceled)
